(19) United States
(12) Patent Application Publication
(10) Pub. No.: US 2014/0044284 A1
(43) Pub. Date: Feb. 13, 2014

(54) REMOTE CONTROLLER

(71) Applicant: Quatius Limited, Hong Kong (CN)

(72) Inventor: Ka Wing Cheung, Hong Kong (CN)

(21) Appl. No.: 13/912,481

(22) Filed: Jun. 7, 2013

(30) Foreign Application Priority Data
Aug. 9, 2012 (CN) 201220394903.9

(51) Int. Cl. H03G 3/02

(52) U.S. Cl. CPC H03G 3/02
USPC 381/105

(57) ABSTRACT

A remote controller is disclosed. The remote controller includes a remote control board, on which a volume up control unit, a volume down control unit and a muting control unit are provided, and the muting control unit is set between the volume up control unit and the volume down control unit. The remote controller is more reasonably designed and more convenient for use.

### FIELD OF THE INVENTION

The present invention relates to a remote controller.

### BACKGROUND OF THE INVENTION

A remote controller is commonly used in the television and acoustic equipment. A remote control board of the remote controller is usually provided with a volume up control unit for increasing volume, a volume down control unit for decreasing volume, and a muting control unit for achieving muting.

In known remote controllers, the volume up control unit and the volume down control unit are set together, and the muting control unit is usually set far away from the volume up control unit and the volume down control unit. In the actual use, the user is familiar with the positions of the volume up control unit and the volume down control unit, but not familiar with the position of the muting control unit, which causes certain inconvenience to operate.

### SUMMARY OF THE INVENTION

Based on this background, it is an object of the present invention to overcome the above-stated problems in the prior art, to provide a remote controller, which is more reasonably designed and convenient for use.

To achieve the above object, the following technical solution is provided:

A remote controller comprises a remote control board, on which a volume up control unit, a volume down control unit and a muting control unit are provided, and the muting control unit is set between the volume up control unit and the volume down control unit.

Preferably, the volume up control unit, the muting control unit, and the volume down control unit are longitudinally arranged on the remote control board.

Preferably, the volume up control unit is close to a front end of the remote control board, and the volume down control unit is close to a rear end of the remote control board.

Preferably, the volume up control unit and the volume down control unit are adjacent to the muting control unit and provided respectively on two opposite sides of the muting control unit.

Preferably, the volume up control unit, the volume down control unit and the muting control unit are integrated into one single piece.

It should be emphasized that the muting control unit, the volume up control unit, and the volume down control unit may be a physical button or a control manner like a touch screen, or the like.

The advantages or principles of the technical solution mentioned above are explained as below.

1. The design is much more reasonable by setting the muting control unit between the volume up control unit and the volume down control unit, and the user, during operation, is very familiar with the positions of the volume up control unit and the volume down control unit, and during the muting operation, the user is able to find the muting control unit to achieve muting much faster, which is more convenient for use.

2. The volume up control unit is close to the front end of the remote control board, and the volume down control unit is close to the rear end of the remote control board. During operation, upper unit is for increasing volume and lower unit is for decreasing volume, which is more suitable for the operation habits of the user.

3. The volume up control unit and the volume down control unit are adjacent to the muting control unit and provided respectively on two opposite sides of the muting control unit, In this way, the operation is easier,

4. The volume up control unit, the volume down control unit and the muting control unit are integrated into one single piece. It is easy for operation, assembly and manufacturing.

### BRIEF DESCRIPTION OF THE DRAWINGS

FIG. 1 is a schematic structural diagram of a remoter controller according to an embodiment.

FIG. 2 is a schematic structural diagram of a remoter controller according to a further embodiment.

### DESCRIPTION OF REFERENCE NUMBERS

10: Remote control board'

20: Muting control unit;

30: Volume up control unit;

40: Volume down control unit;

### DETAILED DESCRIPTION OF THE PREFERRED EMBODIMENTS

The embodiments of the present invention will be further illustrated in the following description.

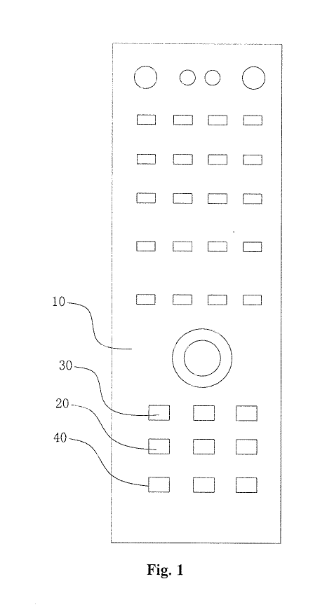

As shown in FIG. 1, a remote controller includes a remote control board 10, which is provided with a volume up control unit 30, a volume down control unit 40 and a muting control unit 20, and the muting control unit 20 is set between the volume up control unit 30 and the volume down control unit 40.

The volume up control unit 30, the muting control unit 20, and volume down control unit 40 are longitudinally arranged on the remote control board 10. The volume up control unit 30 is close to the front end of the remote control board 10, and the volume down unit 40 is close to the rear end of the remote control board 10.

The embodiment has following advantages:

1. The design is much more reasonable by setting the muting control unit 20 between the volume up control unit 30 and volume down control unit 40, and the user, during operation, is very familiar with the positions of the volume up control unit 30 and the volume down control unit 40, and during the operation of muting, the user is able to find the muting control unit 20 to achieve muting much faster, which is more convenient for use.

2. The volume up control unit 30 is close to the front end of the remote control board 10, and the volume down control unit 40 is close to the rear end of the remote control board 10. During operation, the upper unit is for increasing volume and the lower unit is for decreasing volume, which is more suitable for the operation habits of the user.

It shall be emphasized that the muting control unit 20, the volume up control unit 30, and the volume down control unit 40 can be physical buttons (as shown in FIG. 1, the setting of buttons is not limited to the manner of FIG. 1), or control manners like touch screen, or the like.

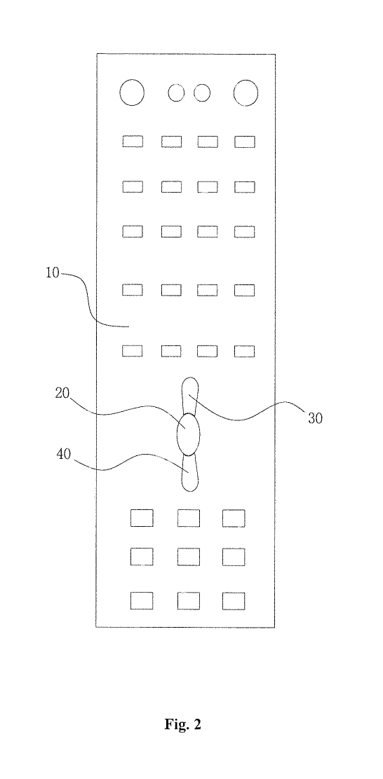

As a choice, the remote controller may be provided as shown in FIG. 2. The volume up control unit and the volume down control unit are adjacent to the muting control unit and provided respectively on two opposite sides of the muting control unit. More preferably, the volume up control unit, the volume down control unit and the muting control unit are integrated into one single piece. It is easy for operation, assembly and manufacturing.

It should be emphasized that the above-described embodiments of the present invention, particularly, any embodiments, are merely possible examples of implementations. Many variations and modifications may be made to the above-described embodiment(s) of the invention without departing substantially from the spirit and principles of the invention. All such modifications and variations are intended to be included herein within the scope of this disclosure.

What is claimed is:

1. A remote controller, comprising:
a remote control board, provided thereon with a volume up control unit, a volume down control unit and a muting control unit; wherein the muting control unit is provided between the volume up control unit and the volume down control unit.

2. The remote controller of claim 1, wherein the volume up control unit, the muting control unit, and the volume down control unit are longitudinally arranged on the remote control board.

3. The remote controller of claim 2, wherein the volume up control unit is close to a front end of the remote control board, and the volume down control unit is close to a rear end of the remote control board.

4. The remote controller of claim 2, wherein the volume up control unit and the volume down control unit are adjacent to the muting control unit and provided respectively on two opposite sides of the muting control unit.

5. The remote controller of claim 4, wherein the volume up control unit, the volume down control unit and the muting control unit are integrated into one single piece.
